(19) United States
(12) Patent Application Publication
(10) Pub. No.: US 2024/0235000 A1
(43) Pub. Date: Jul. 11, 2024

(54) DEVICE FOR INTERACTING WITH ELECTROMAGNETIC RADIATION

(71) Applicant: COMMONWEALTH SCIENTIFIC AND INDUSTRIAL RESEARCH ORGANISATION, Australian Capital Territory (AU)

(72) Inventors: Andrew SQUIRES, Australian Capital Territory (AU); Jia DU, Australian Capital Territory (AU); Timothy Anthony VAN DER LAAN, Australian Capital Territory (AU)

(21) Appl. No.: 18/560,896

(22) PCT Filed: May 13, 2022
(86) PCT No.: PCT/AU2022/050458

§ 371 Date: Nov. 14, 2023

(30) Foreign Application Priority Data
May 14, 2021 (AU) 2021901438

(51) Int. Cl. H01P 7/06; H01P 7/10; H01P 11/00; H01Q 15/14; H03J 3/16

(52) U.S. Cl. CPC H01P 7/065; H01P 7/10; H01P 11/008; H01Q 15/14; H03J 3/16

(57) ABSTRACT

This disclosure relates to chips, and methods for manufacturing devices, that interact with electromagnetic radiation. A method for manufacturing a device comprises disposing an unpatterned graphene layer on a substrate, which comprises an unpatterned metal layer to form an unpatterned graphene-metal bi-layer attached to a surface of the substrate. The method then comprises patterning the bi-layer through the graphene layer and the metal layer with a design that comprises one or more superimposed trenches. Each of the one or more trenches extend through the graphene layer and the metal layer to provide interaction with electromagnetic radiation.

### CROSS-REFERENCE TO RELATED APPLICATIONS

The present application claims priority from Australian Provisional Patent Application No 2021901438 filed on 14 May 2021, the contents of which are incorporated herein by reference in their entirety.

### TECHNICAL FIELD

This disclosure relates to chips, and methods for manufacturing chips, that interact with electromagnetic radiation.

### BACKGROUND

A wide range of antennas and other devices that absorb electromagnetic radiation are available for various different applications scenarios but challenges still remain for their design. In particular, as the frequency of electromagnetic radiation that is to be absorbed by the devices increases, conventional designs become ineffective. That is, the amount of energy from the electromagnetic radiation absorbed by the devices becomes insufficient mainly because metal conductors used in conventional antennas become lossy at high frequencies and therefore lead to a reduction in effectiveness.

In the terahertz (THz) range, there are theoretical designs of new materials and devices that show in simulations that they absorb electromagnetic radiation, but their manufacturing remains challenging. As a result, few experimental results and few physical example antennas are available. Therefore, there is a need for an absorber that is effective, with tuneability or reconfigurability, and that has a design that can be realised physically.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each of the appended claims.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY

This disclosure provides a device that interacts with electromagnetic radiation in the sub-terahertz wavelength range, for example. The disclosed device comprises a dielectric layer overlayed by a bi-layer of a metallic conductive material, such as gold, for frequency-selective interaction, such as absorption, and graphene for tuneability. The bi-layer is patterned together to provide a superimposed pattern on the conductive metal and the graphene. As a result, the chip provides the interaction, with the tuneable amplitude and frequency by adjusting a bias voltage applied on the graphene, and can be manufactured by depositing the conductive metal first, the graphene second and then patterning both by a two-step etching process. Further, in some areas, the graphene comes into direct contact with the dielectric layer, which results in improved adhesion of the graphene to the chip.

A method for manufacturing a device comprises:
disposing an unpatterned graphene layer on a substrate comprising an unpatterned metal layer to form an unpatterned graphene-metal bi-layer attached to a surface of the substrate; and
patterning the bi-layer through the graphene layer and the metal layer with a design comprising one or more superimposed trenches:
   wherein each of the one or more trenches extend through the graphene layer and the metal layer to provide interaction with electromagnetic radiation.

In some embodiments, the patterning is performed using a single mask defining the design to thereby create the trenches through the graphene layer and the metal layer in a single patterning step.

In some embodiments, the method further comprises using the single mask for performing both of etching of the graphene layer and etching of the metal layer.

In some embodiments, the method further comprises:
etching the graphene layer with a first etching agent; and
after etching the graphene layer, etching the metal layer with a second etching agent.

In some embodiments, etching the graphene layer comprises use of oxygen plasma and etching the metal layer comprises use of argon plasma.

In some embodiments, the method further comprises disposing the unpatterned metal layer on the substrate.

In some embodiments, the method further comprises creating a gap in the metal layer to define a first electrode and a second electrode.

In some embodiments, creating the gap comprises using a mask on the metal layer and etching the metal layer or using a directed beam.

In some embodiments, the gap is created prior to disposing the unpatterned graphene layer on the substrate.

In some embodiments, the method further comprises cleaning the device with oxygen plasma during, or after, the patterning.

In some embodiments, patterning the bi-layer comprises using a directed beam to create the one or more trenches in the graphene layer and the metal layer of the bi-layer.

A device comprises:
a support layer having a first surface;
a patterned graphene-metal bi-layer comprising a metal layer attached to the first surface and a graphene layer attached on the metal layer, the bi-layer comprising one or more superimposed trenches that extend through the graphene layer and the metal layer to provide interaction with electromagnetic radiation;
wherein
   the superimposed trenches align across the graphene layer and metal layer by patterning the bi-layer,
   the metal layer comprises a gap to define a first electrode including the one or more superimposed trenches and a second electrode, and
   the first electrode is connected to the second electrode by the graphene layer to provide tuneability by modifying a voltage applied between the first electrode and the second electrode and across the graphene layer parallel to the first surface.

In some embodiments, the second electrode is on top of the graphene.

In some embodiments, the one or more trenches define an array and the array extends across the bi-layer.

In some embodiments, the array is a periodical design to provide the interaction with electromagnetic radiation by the device.

In some embodiments, the patterned bi-layer forms a meta-material structure.

In some embodiments, the support layer is a dielectric layer.

In some embodiments, the device comprises a resonance structure comprising the dielectric layer, the resonance structure being tuneable by the voltage applied across the graphene layer to thereby tune the interaction with the electromagnetic radiation.

In some embodiments, the dielectric layer has a second surface opposite the first surface, and the device further comprises a reflective conductive layer disposed on the second surface to reflect electromagnetic radiation, propagated through the dielectric layer, back into the dielectric layer to form a resonance in the dielectric layer.

In some embodiments, the support layer is composed of a glass fibre and Polytetrafluoroethylene (PTFE) composite.

In some embodiments, the electromagnetic radiation has a frequency between 1 GHz and 3 THz.

In some embodiments, the electromagnetic radiation has a frequency between 100 GHz and 3 THz.

In some embodiments, the electromagnetic radiation has a frequency greater than 100 GHz.

In some embodiments, the metal layer is composed of gold.

In some embodiments, the metal layer is thicker than the skin depth of the electromagnetic radiation in the metal layer.

In some embodiments, the graphene layer extends beyond the metal layer to directly attach to the support layer.

In some embodiments, the graphene layer directly attaches to the support layer at one or more of:
the gap between the first electrode and the second electrode; and
an area on the perimeter of the metal layer.

A device comprises:
a support layer having a first surface;
a metal layer disposed on the first surface;
a graphene layer disposed on the metal layer, wherein
the metal layer and the graphene layer form a bi-layer,
the graphene layer extends beyond the metal layer to directly attach to the support layer.

In some embodiments, the support layer is a dielectric layer.

In some embodiments, the graphene layer is directly attached to the support layer by an attracting force between the graphene layer and the support layer

In some embodiments, the bi-layer comprises one or more trenches to provide interaction with the electromagnetic radiation with the bi-layer, and
the one or more trenches extends through the graphene layer and the metal layer.

A method for manufacturing a device comprises:
disposing a metal layer on a support layer, wherein an area of the support layer is exposed;
disposing a graphene layer on the metal layer to form a bi-layer comprising the metal layer and the graphene layer and to bring the graphene layer into direct contact with the exposed area of the support layer.

### BRIEF DESCRIPTION OF DRAWINGS

An example will now be described with reference to the following drawings:

FIG. 1 illustrates a chip for absorbing electromagnetic radiation

FIG. 2 illustrates a further example chip.

FIG. 3 illustrates yet a further example chip.

FIG. 4 illustrates a method for manufacturing a chip.

FIG. 5 illustrates another method for manufacturing a chip.

FIG. 6 illustrates an experimental setup: terahertz time domain spectroscopy in reflection geometry. The terahertz wave is reflected off the graphene/gold bilayer metasurface acting as a single port device.

FIG. 7 provides a schematic of the graphene/gold bilayer metasurface incorporated into a 0.2 THz frequency selective absorber: Top panels showing the unit cell and array structure, bottom right panel depicting the graphene/gold structure on 0.254 mm Rogers5880LZ substrate and bottom left panel displaying an image of the fabricated device.

FIG. 8 illustrates a cross section of the 0.2 THz frequency selective absorber indicated from the intersecting black plane in FIG. 7.

FIG. 9 illustrates a SEM image of pattern 108. The arms of each cross are about 100 μm long. The photo was taken with EHT=5 kV, Mag=118X, WD=5.1 mm, Aperture size=30.00 μm.

FIG. 10 shows the S11 parameter obtained from the experimental setup in FIG. 6. Clear frequency tuning of 5 GHz and amplitude tuning of 16 dB (approx. 97.5%) of the 0.2 THz resonance is observed with an applied DC voltage from 1-6V.

FIG. 11 shows a Broadband response of the device with 0V and 6V applied voltage. Clear resonances and broadband modulation is observed.

FIG. 11 shows S11 parameter of the designed 0.2 THz resonance, showing clear frequency tuning of 5 GHz and amplitude tuning of 16 dB (approx. 97.5%). Top and bottom panels represent a reversal of voltage connections.

FIG. 13 shows voltage characteristics of the 0.2 THz mode. Peak position, S11 parameter, FWHM and peak area all show nonlinear behaviour with systematic change in the region above 3V applied voltage.

FIG. 14 shows the broadband response of the absorber: Left panel gives a comparison of the gold/graphene bilayer metasurface (red) with its gold only counterpart (black). All plasmonic modes between n 0.2-0.6 THz are reproduced with increase loss and slight frequency shift. Modes above 0.6 THz are not reproduced in the bilayer. The right panel shows the full frequency response of the bilayer with applied voltage. Frequency and amplitude tuning is observed for each resonance superimposed on a broadband modulation.

FIG. 15 shows simulated S11 parameter of the gold-only metasurface response at 0.2 THz.

FIG. 16 shows the broadband modulation depth of the bilayer. Discontinuities are seen at resonant frequencies due to the frequency shift of these modes with the applied field.

FIG. 17 illustrates (a) Experimental comparison the graphene/gold bilayer metasurface (bottom line) with its gold-only counterpart (top line). The 0.2 THz absorption is reproduced with increased amplitude and slight frequency redshift. (b) Simulated Su parameters of the graphene/gold metasurface (bottom line) with its gold-only counterpart (top line). The increase in resonant amplitude and redshift of the mode is produced in both experimental and simulation results, with strong agreement observed between them.

### DESCRIPTION OF EMBODIMENTS

Electronic systems at THz frequency bands are usually accompanied by relatively high spurious tones and parasitic intermodulation due to the frequency multiplication, heterodyne mixing and amplification networks. State-of-the-art frequency-selective absorbers are desired for eliminating these unwanted interferences at specific frequencies whilst giving little attenuation on the available signal. Their absorption amplitudes or frequencies should be electrically tuneable for overcoming the unpredictability of parasitic interferences and thus greatly increasing the flexibility for signal processing. However, electrically tuneable frequency-selective THz absorbers, with suitably high-quality factor resonances, remain elusive. A possible architype in realising these desired high-quality resonances lies in the realm of THz metamaterials as disclosed herein.

Metamaterials consist of a periodic array of subwavelength unit cells, which exhibit properties outside those attainable from natural materials. These structures imitate the periodicity of the crystal lattice and allow control of the response to, and manipulation, of the amplitude, polarization, and phase of electromagnetic radiation.

Graphene is a two-dimensional (2D) material with unique features that make it a strong candidate for the next generation of THz electronics devices: (i) a high charge carrier mobility allowing ultrafast response to electric and magnetic fields, required at THz frequencies: (ii) a Dirac band structure with linear dispersion resulting in charges behaving as massless Dirac Fermions, where the Fermi level and thus conductivity can be tuned with the application of an external field.

### Terahertz Radiation

This disclosure provides a patterned device chip for absorbing THz electromagnetic radiation. In a general sense, a chip is a small piece of material with a particular function implemented thereon. In many examples, a chip has a dielectric substrate that is used as a carrier for functional elements that are integrated on the same substrate. Many chips are manufactured as digital processing chips on a silicon substrate using lithography but other applications and substrates are possible. Here, the disclosed chip is also manufactured on a substrate, such as Polytetrafluoroethylene (PTFE), and the functional elements are applied on the substrate to provide for absorption of electromagnetic radiation by the chip. In one example, the substrate is a Rogers5880 high frequency laminate circuit board. It is a PTFE composite reinforced with glass microfibers and consists of about 70% PTFE. In other examples, the substrate may be flexible substrates such as PTFE, polyimide and other polymers/plastics, or sapphire, MgO, silicon. The disclosed chip is particularly useful in the sub-millimetre (sub-mm) wavelength band, although there is no strictly physical limitation for the application to longer wavelengths. In this sense, the disclosed chip may be designed to work for millimetre or longer waves, but it is expected that other technologies outcompete the proposed chip on costs. Therefore, the main application area is expected to lie in the sub-mm band.

The International Telecommunication Union (ITU) defines Extremely High Frequency (EHF) as 30 to 300 Gigahertz (GHz), which relates to a wavelength of 10-1 mm. Tremendously High Frequency (THF) is then defined as frequencies from 0.3 to 3 terahertz (THz), and roughly occupies the band between microwaves and infrared light. Within this ITU definition, it is expected that some examples of this disclosure apply the upper end of the EHF frequency band and the THF frequency band. This band is also referred to as Terahertz band, and can be defined as 0.1 to 10 THz. In the Terahertz band, technologies for absorption of electromagnetic radiation is in its infancy. Some examples disclosed herein can absorb electromagnetic radiation in the Terahertz band. It is noted however, that the principles disclosed herein may find applications outside the Terahertz band.

One example application is in the sixth generation (6G) of mobile communication. While the current fifth generation (5G) occupies bands from 30 to 300 GHz, future 5G bands and 6G bands are expected to lie in the Terahertz band. Like mm-band communications, terahertz bands can be used as mobile backhaul for transferring large bandwidth signals between base stations. Another venue for fiber or copper replacement is point-to-point links in rural environments and macro-cell communications.

More importantly, terahertz bands can be employed in close-in communications, also known as whisper radio applications. That includes wiring harnesses in circuit boards and vehicles, nanosensors, and wireless personal area networks (PANs). Then, there are applications like high-resolution spectroscopy and imaging and communication studies that use short-range communications in the form of massive bandwidth channels with zero error rate in crucial areas like coding, redundancy, and frequency diversity.

### Chip

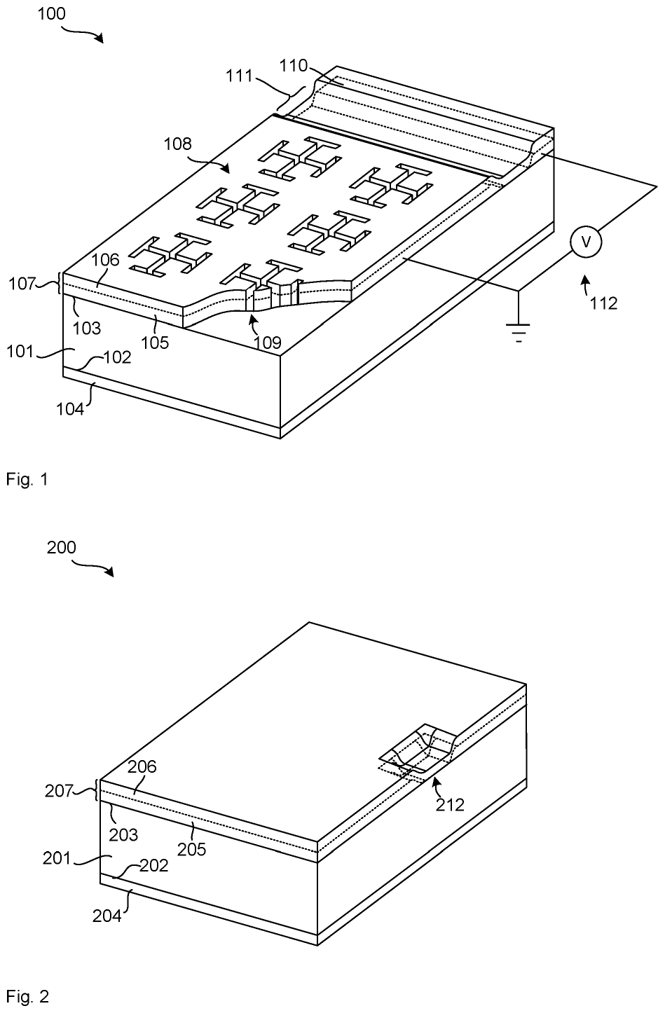

FIG. 1 illustrates a chip 100 for interacting with (including but not limited to absorption of) electromagnetic radiation, such as radiation in the THz band. A chip in this context is a small electronic device that is manufactured on a thin substrate. In one application, chip 100 may be designed to absorb the radiation as its interaction and is therefore referred to as an absorber of electromagnetic radiation or simply absorber. In other applications, chip 100 may work as a sensor, for example. In yet further examples, the chip 100 is designed for reflection, refraction, diffraction and deflection. All wave-matter interactions can be reduced to these four interactions above. Therefore, chip 100 may also be designed for absorption, interference, modulation, steering, transmission, polarisation, phase shift, amplification, dampening, focusing and potentially further interactions. As disclosed herein, the geometric design of the chip determines which of the above functions are implemented. While chip 100 is shown on its own, it is to be understood that chip 100 may be interfaced by electrical connections and packaged with a suitable casing or integrated with other components on the same substrate or on separate substrates.

### Support Layer

Chip 100 comprises a support layer 101, which is also referred to herein as a dielectric layer 101, having a bottom surface 102 and a top surface 103 opposite the bottom surface 102. In some instances described herein, the top surface 103 is referred to as the “first surface” while the bottom surface 102 is referred to as the “second surface”. The dielectric layer 101 may be made of a variety of materials that are essentially transparent, that is, has low absorption, for the electromagnetic radiation to be absorbed by chip 100. Typically, dielectric materials are insulating or a very poor conductor of electric current. In some examples, the dielectric constant of the dielectric material may be ε₀≈10-100 or lower, and the dissipation factor may be 0.002 to 0.003 at 10 GHz. A wide range of materials can be used, including ceramics, air and polymers. The dielectric layer 101 may be made from many dielectric materials, such as, for example, most metal oxides like SiO₂ and MgO, a glass fibre or sapphire. In some examples, the dielectric layer 101 may comprise multiple layers of dielectric materials. The dielectric layer may also be a vacuum layer although the mechanical arrangement may become challenging in that case. In other examples, the dielectric layer 101 is made of Polytetrafluoroethylene (PTFE) and may be a composite or laminate material. In some examples disclosed herein, the dielectric layer 101 is a RT/duroid 5880LZ Laminate board by the Rogers Corporation. During manufacturing the sensor 100, as described in more detail below, the dielectric layer can be used as a starting point. Therefore, the dielectric layer is also referred to herein as a ‘substrate’.

### Reflective Layer

Chip 100 further comprises a grounding electrode 104, which is essentially a reflective conductive layer, disposed on the bottom surface 102 to reflect electromagnetic radiation, propagated through the dielectric layer 101, back into the dielectric layer 101 to form a resonance in the dielectric layer 101. The grounding electrode 104 may be made of a variety of different reflective conductive materials, including metals, such as aluminium, copper, and others. In another example, reflective layer can be graphene, or a graphene/metal bi-layer. The grounding electrode 104 may also be made of a doped semiconductor. In one example, the grounding electrode 104 is made of gold, which has the advantage of good conductivity and ease of manufacturing. When in use, the grounding electrode 104 may be connected to ground or another reference potential.

### Bi-Layer

There is also a metal layer 105 and a graphene layer 106, which together form a bi-layer 107. The metal layer 105 is disposed on the top surface 103 and is configured, by patterning an array of slot antennas, to interact with the electromagnetic radiation that is in the resonance in the dielectric layer 101 by way of reflection by the bottom reflective layer 104, which can be tuned by applying a voltage to the graphene layer 306.

Again, the metal layer 105 may be made of a range of metals and metal alloys, including, Ti/Au, Cr (chromium), W(tungsten), aluminium and copper. In some examples disclosed herein, the metal layer 103 is made of gold, noting that the bottom reflective layer 104 and the top metal layer 105 can be made of the same material or of different materials. The thickness of the metal layer is greater than the skin depth of the electromagnetic radiation in the metal layer, for example, 167 nm for gold at 0.2 THz. The skid depth is the depth below the surface of a conductor where the amplitude of the electromagnetic wave has been attenuated below 1/e of its amplitude at the surface.

Disposed on the top metal layer 105 is the graphene layer 106. The graphene layer 106 provides tuneability to the resonance when applied with a DC bias voltage and thereby to the absorption of the graphene/metal bilayer meta-structure 107. As a result of the graphene layer 106 being disposed on the metal layer 105, the metal layer 105 and the graphene layer 106 form a bi-layer 107. The term ‘bi-layer’ is used herein to indicate that the graphene 106 and metal 105 essentially form a single electrode layer that has two parts, that is, the metal layer 105 and the graphene layer 106. Together, the metal layer 105 and graphene layer 106, as the bi-layer 107, form a same meta-structure or meta-material that has properties that are particularly advantageous for absorbing electromagnetic THz radiation and with amplitude and frequency tuneablity. A meta-structure or meta-material (which can be simply referred to as a meta-material structure) is typically any material engineered to have a property that is not found in naturally occurring materials. A meta-material structure, such as the graphene/metal bi-layer 107, may also comprise a metasurface which is able to modulate the behaviours of electromagnetic waves through specific boundary conditions.

As the metal layer 105 and graphene layer 106 form the bi-layer 107, the bi-layer is continuous, which means that it forms a single electrode. This is in contrast to other designs where there are multiple islands of metal and graphene layers that are discontinuous. Those islands may be connected by separate wires or other means but in those cases, the bi-layer is not continuous. Here, both the metal layer 105 and the graphene layer 106 are continuous (i.e. unbroken) as the continuous bi-layer. In other words, the pattern 108 comprises voids where parts of the bi-layer has been removed. As a result, those voids are surrounded by the continuous bi-layer, which means the bi-layer is not broken up by the pattern. In a geometrical sense, every point in the active area of the bi-layer around the pattern is reachable from every other point in that area via only the bi-layer. That is, no wires or other structures are required between any two points in the active area of the bi-layer around the pattern. In view of the above disclosure, it would also be appropriate to refer to the bi-layer is a continuous interaction layer.

In other words, the bi-layer is continuous and spans across a substantial portion of the first surface prior to patterning and covers the entire section of the patterns. Furthermore, after patterning the bi-layer, the bi-layer is still continuous and spans across a substantial portion of the first surface of the support layer. The bi-layer also constitutes a bound or tightly bound graphene-metal meta-structure that spans across the surface of the substrate forming a continuous tuneable conductive layer. If viewed from above, one can see that the bi-layer is continuous from left to right, as well as from top to bottom. The bi-layer is continuous from left to right, in the sense that there exists an unbroken/uninterrupted line or path starting at the left edge of the bi-layer and terminating at the right edge of the bi-layer. The bi-layer is continuous from top to bottom with the same meaning.

When a voltage is applied to the graphene layer 106, the conductivity of the graphene layer 106 changes. To this end, device 100 comprises an electrode 110, which is separated or isolated from metal layer 105 by a gap 111. As a result, metal layer 105 acts as a second electrode and a voltage can be applied between electrode 110 and metal layer 105, creating an electric field that is essentially parallel to bi-layer 107. It is noted that the graphene layer 106 is connected to the metal layer 106 and the electrode 110. The conductivity of the graphene layer is sufficiently high for the interaction with the electromagnetic radiation but sufficiently low to enable a voltage to appear between the metal layer 105 and the electrode 110. That is, the graphene layer 106 does not present a short that would force the voltage to zero. In some examples, the resistance of the graphene layer 106 is in the range of tens of Ohm (10-100Ω). This behaviour may be supported by dislocated graphene sheets forming the graphene layer 106 as opposed to a layer of fully (vertically) connected carbon atoms.

Graphene is a sheet of a two-dimensional layer of sp²-bonded carbon atoms in a hexagonal lattice. Graphene's carrier dynamics are governed by intraband electron transitions described by the Kubo formalism. These produce ultrafast carrier mobilities (up to 200 000 cm²V⁻¹s⁻¹ at low temperature), which is well beyond values observed in Silicon (1400 cm²V⁻¹s⁻¹). Furthermore, the fermi level, E_{F}, of graphene can be controlled via an external electric field. As such, the complex conductivity of the graphene film can be tuned with an applied voltage, which provides the tuneability disclosed herein.

The term “graphene layer” means that the layer contains graphene but the graphene layer is not necessarily a single layer of graphene with a single atom thickness. In that sense, the graphene layer may be a mono-layer (single layer of graphene), a few-layer (1-100 layers of graphene), or a multi-layer (more than 100 layers of graphene). In one example, the graphene layer 106 has about 50 layers of graphene. The ‘layers above may synonymously be referred to as sheets. It is noted that there is no substrate or support included in the device other than the metal layer 105.

### Patterned Bi-Layer

The bi-layer 107 is patterned by a pattern 108 to provide interaction with the electromagnetic radiation by the chip. The pattern may be considered to be a superimposed trench or an array of superimposed trenches. The superimposed trenches may align across the graphene layer and metal layer by patterning the bi-layer simultaneously. In other words, the superimposed trenches are aligned across the boundary of the metal layer and graphene layer by patterning of the bilayer simultaneously. Each of the one or more trenches extend through the graphene layer and the metal layer to provide interaction with electromagnetic radiation by the chip. The word “trench” is used to refer to a relatively narrow opening in a material or structure with vertical walls and long dimensions that extend through the material or structure. While trenches may be thought of as vertical “cut-outs” of a material, in this disclosure, the superimposed trenches are not limited to this configuration. In this disclosure, a trench may be of any shape or design that extends through the bi-layer. This can also be considered as patterning of the bi-layer that results in trenches or cuts in the graphene layer and the metal layer and superimpose as a single design. The trenches may also be considered as “slots”.

The patterned bi-layer may also define an active area or an interaction area that is a sub-area of the first surface of the dielectric substrate. This active area is the area where interaction with electromagnetic radiation occurs due to the bi-layer that spans the area, which contains the superimposed trenches.

As seen at numeral 109 in FIG. 1, the pattern 108 extends through the graphene layer 106 and the metal layer 105. This means, the pattern extends all the way through the bi-layer 107 down to the dielectric layer (101). As a result, the pattern in the graphene layer 106 and the pattern in the metal layer (105) superimpose on each other as a single pattern through the bi-layer 107. Both the metal layer and the gold layer are patterned only after formation of the bi-layer.

The term “at least in part” means that the pattern does not have to extend through the bi-layer 107 everywhere on the chip 100. In the example of FIG. 1, there are essentially three regions: (1) the pattern 108 extends through the entire bi-layer 107 where the cross-shapes are created, (2) where, at 111, the graphene layer extends over the substrate 101 and (3) where the electrode 110 is formed by a separate area of metal layer.

It is noted that the term ‘pattern’ herein refers generally to areas, shapes or geometries where material is present or absent compared to other areas. That may be achieved by material being added or removed in those areas. In many examples, due to manufacturing processes used, the first step may be depositing a continuous layer of the material, such as the metal/graphene bi-layer 107, and then removing the material in defined areas to create the ‘pattern’. It is noted that the term ‘pattern’ does not necessarily relate to something repetitive or regular. Instead, the ‘pattern’ can be entirely irregular. Typically, patterns are designed by use of computer aided design (CAD) tools as physical layout, simulated, and then realised using manufacturing processes, such as mask-based lithography. In this sense, manufacturing the device may comprise patterning the bi-layer through the graphene layer and the metal layer simultaneously with a design comprising one or more superimposed trenches.

In some examples, the pattern comprises a periodic 2D array structure as shown in FIG. 1. This may involve a regular repetition of identical structures, such as the Jerusalem crosses in FIG. 1. As a result of this periodic structure, the pattern imitates the interaction of an atomic structure of a material with electromagnetic radiation. However, that material does, in most cases, not exist as such. Therefore, the patterned bi-layer is referred to as a meta-material in those cases.

### Resonator Antenna

In essence, chip 100 presents a dielectric resonator antenna (DRA), where radio waves enter the dielectric layer 101 through the openings of the pattern 108 slots and then bounce back and forth between the reflecting layer 104 and the bi-layer 107 to form a standing wave. The frequency of that standing wave, and therefore the absorption frequency, depends on the material properties of the bi-layer 107 and the designed meta-structure 108. In other words, the thickness of dielectric layer together with its dielectric constant determines the resonator frequency of the designed meta-structure. While the thickness and permittivity of the dielectric layer 101 and the material properties of the reflective layer 104 are unchanged during operation, the material properties of the bi-layer 107 can be tuned by applying a voltage to the graphene layer 106, that is, between electrode 110 and the metal layer 105, as discussed above.

### Tuning

The voltage between electrode 110 and metal layer 105 alters the conductivity of the graphene layer 106 and hence, the impedance matching of the electromagnetic wave into the chip, altering the resonance behaviour. In other words, the device represents an RLC resonance structure, where the graphene layer 106 represents the resistor R, the connectors and metal layer form the inductance L, and the dielectric layer 101 and grounding electrode 104 represent the capacitance C. Applying the voltage between electrode 110 and metal layer 105 alters the resistance of R. As a consequence, the change of conductivity of the graphene alters the intraband absorption of the electromagnetic wave, altering the broadband interaction through the device.

In other words, the device comprises a resonance structure comprising the dielectric layer, the resonance structure being tuneable by the voltage applied across the graphene layer to thereby tune the interaction with the electromagnetic radiation. In an example, the resonance structure consists of a dielectric layer sandwiched between two electrodes. The conductivity of the graphene/metal bilayer metasurface is tuneable by way of changing the bias voltage (by changing the voltage applied to the electrodes) to change the resonance properties (such as the peak, frequency, Q-factor).

Electrode 110 may be made of conducting material and advantageously of the same material as metal layer 105, such as gold, to simplify manufacturing. In an example, electrode 110 is separated from the metal layer 105 by an opening 111, such as a trench or gap. In this sense, metal layer 105 comprises an opening (or gap) to define a first electrode including the one or more trenches for interacting with the electromagnetic radiation and a second electrode for applying the bias voltage. The first electrode would correspond to the electrode that is part of the bi-layer and therefore, contains the patterning (superimposed trenches). The second electrode defined by opening 111 corresponds to electrode 110. Despite the opening 111 separating the first and second electrode, the first electrode is connected to the second electrode by the graphene layer 106. This enables application of a voltage between the first and second electrode and parallel to the first surface of the substrate, which enables tuning of the conductivity of the graphene. FIG. 1 shows how the bias voltage is applied by circuit 112. Parallel to the first surface means that the vector of the electric field (equipotential lines) between the electrodes is substantially parallel to the first surface. That is, there may be a small angle between the electric field vector and the first surface as long as the electric field is generally between two electrodes that sit side-by-side. This is in contrast to an electric field that intersects the first surface, such as an electric field between the metal layer 105 and the grounding electrode 104.

In an example, because of opening 111, the graphene layer 106 can attach directly to the support layer. As a result, the graphene layer 106 strongly attaches to the device as forces (such as Van der Waals forces) can be established between the graphene and the support layer. These forces can also be referred to as an attracting force. This allows the metal layer 105 to better attach to the support layer, as the graphene layer 106 strongly adheres to the device due to directly attachment to the support layer via the opening 111.

Opening 111 can be manufactured by forming metal layer 105 at the same time as electrode 110 while defining the opening 111 by way of a mask. In an example, the opening 111 can be formed by using a mask on the metal layer and etching the metal layer or using a directed beam. Using a directed beam, such as a focused ion beam, does not need a mask in order to create opening 111. In this example, opening 111 is created prior to disposing the unpatterned graphene layer on the substrate.

The distance between the electrode 110 and the metal layer 105, that is the width of gap 111, can be very small as long as electrical discharge from 105 to 110 does not occur. In some examples, the distance is 3-4 mm but can be as small as 100 nm.

In another example, as opposed to creating a gap by etching the metal layer, electrode 110 may be formed on top of the graphene layer 106. A bias voltage can still be created between electrode 110 and the electrode that forms part of the bi-layer, which is used to tune the conductivity of the graphene. This example is also referred to as a voltage that is parallel to the first surface. In this example, electrode 110 may be formed by using a mask on the graphene layer and depositing a metal on the device. The metal can be deposited on the device using a sputtering technique, for example. As a result, electrode 110 can still be considered as part of the metal layer with a gap that defines a first electrode (part of the metal layer that forms the bi-layer) and a second electrode (electrode 110). In this sense, the gap is defined is such a way that it insulates the first and second electrode from one another. This definition similarly applies to the example, where opening 111 defines the first and second electrode. In the example where electrode 110 is on top of the graphene layer, the first and second electrode may overlap vertically or there may be a horizontal separation between the two electrodes.

In yet a further example, two electrodes can be formed on top of graphene layer 106 as well as one on each side of the graphene layer 106. However, this example may lead to a reduction in the interaction with electromagnetic radiation with the device, as some electromagnetic radiation is reflected by the metal electrodes placed on top of the graphene layer. This configuration may also reduce the ability to tune the graphene layer with a bias voltage and may be difficult to manufacture as the first electrode would not easily adhere to the graphene layer.

Since the chip 100 is tuned by way of an applied voltage, the absorption characteristics can be changed rapidly. For example, the chip 100 can be tuned based on a modulation frequency to de-modulate the received electromagnetic radiation into the base-band in order to extract data symbols for communication, such as by use of a QPSK modulation scheme.

The pattern 108 can be designed to filter desired electromagnetic waves. The size and shape of the pattern can be chosen such that waves of a particular polarization or of a particular wavelength are transmitted while other waves are reflected away from chip 100. The pattern 108 further determines the direction from which waves can be transmitted similar to the principles of slot antennas and design methodologies from that field can be applied here to design pattern 108.

It has been found that the absorption of the electromagnetic radiation increases significantly when the graphene layer 106 and the metal layer 105 are both patterned together compared to only patterning the metal layer 105 and disposing a continuous graphene layer without pattern on top of the metal layer 105. However, patterning the metal layer 105 first, and then adding the graphene to the pattern so that the same pattern is created in the graphene layer 106 is very difficult to achieve due to the difficult handling characteristics of graphene. The proposed solution provides for a method that results in a patterned bi-layer (comprising metal and graphene layers) that can be readily replicated with a realistic manufacturing process.

While some of the examples above use a resonant structure involving the dielectric layer 101 and grounding electrode 104, other examples may use other effects to realise an interaction with the electromagnetic radiation. For example, at higher frequencies above 1 THz, plasmon resonance on the surface of the bi-layer 107 may be the main factor for the interaction and the dielectric layer 101 and grounding electrode 104 may not be necessary. Nevertheless, the interaction, such as the plasmon resonance, can still be tuned by applying a voltage across the graphene layer 106. As a result, the overall range of applicability of the bi-layer may be between 1 GHz and 3 THz, with specific advantages over other approaches in the range between 100 GHz and 3 THz. In other words, the disclosed approach is particularly useful above 100 GHz.

### Attachment Areas

FIG. 2 illustrates a further example chip 200 comprising a dielectric layer 201 as above and having a bottom surface 202 and a top surface 203. Again, a reflective conducting layer 204 is disposed on the bottom surface 202 to reflect electromagnetic radiation and facilitate resonance. A metal layer 205 is disposed on the top surface 203 and is configured to absorb the electromagnetic radiation that is in the resonance in the dielectric layer 201. A graphene layer 206 is disposed on the metal layer 205 to provide tuneability to the resonance and thereby to the absorption of the metal layer 205. As explained with reference to FIG. 1, the metal layer 205 and the graphene layer 206 form a bi-layer 207. In this example of FIG. 2, there is an area 212 where the metal layer 205 does not extend over the dielectric layer 201. This may be achieved by not depositing metal over that area, or by removing metal from that area after depositing the metal. In some examples, area 212 may be considered an opening in the metal layer 205. In effect, in the area 212 the dielectric layer 201 is exposed since it is not covered by the metal layer 205. As a result, the graphene layer 206 is laid over the metal layer 205, the graphene layer 206 extends beyond the metal layer 205. As a result, the graphene layer 206 attaches directly to the dielectric layer 201.

Physically, this means that the carbon (C) atoms of the graphene layer 206 are in very close proximity to the atoms of the dielectric layer. In one example, the proximity is sufficiently close such that short-range Van der Waals forces attract the graphene layer 206 to the metal layer 201. This is particularly useful for graphene because graphene is a very regular structure which provides a high density of C atoms that each add to the attractive force that would otherwise be very weak for a single atom. In one example, the distance between the C atoms and the atoms of the dielectric layer 201 is less than 1 nm or between 0.6 nm and 0.4 nm.

Directly attaching to the dielectric layer 201 means that the graphene layer 206 is in direct contact with the dielectric layer and there is no other substance, such as an adhesive, between the graphene layer 206 and the dielectric layer 201. As a result, the graphene layer 206 and the dielectric layer are not inseparable, since the Van der Waals force can be overcome by forcing the graphene layer 206 away from the dielectric layer 201. However, this can be reversed, and the graphene layer 206 re-attached by again bringing both layers into direct contact.

As a result of the attraction between the graphene layer 206 and the dielectric layer 201, the graphene layer 206 is less likely to peel off the chip 200. In particular, it is possible to design multiple areas where the graphene layer 206 is directly attached to the dielectric layer 201 and these areas may be distributed across the chip 200. This way, the graphene layer 206 is attached at multiple points, which provides for a secure mechanical connection of the graphene layer 206. It is noted that the metal layer 206 is conductive and therefore, Van der Waals forces do not provide a significant attractive force. As a result, graphene has been observed to peel off gold surfaces, which makes subsequent processing almost impossible. The proposed chip provides a solution to that problem by securing the graphene layer more firmly.

Since the resulting bi-layer 207 has the advantage of a relatively secure mechanical connection it is now significantly easier to pattern the bi-layer 207, since there is less risk that the graphene layer 206 peels off during the patterning. In particular, it is now possible to create a pattern as shown in FIG. 1 on the bi-layer 207 that extends all the way through the graphene layer and metal layer 205 down to the dielectric layer 101 to create an absorber for electromagnetic THz radiation.

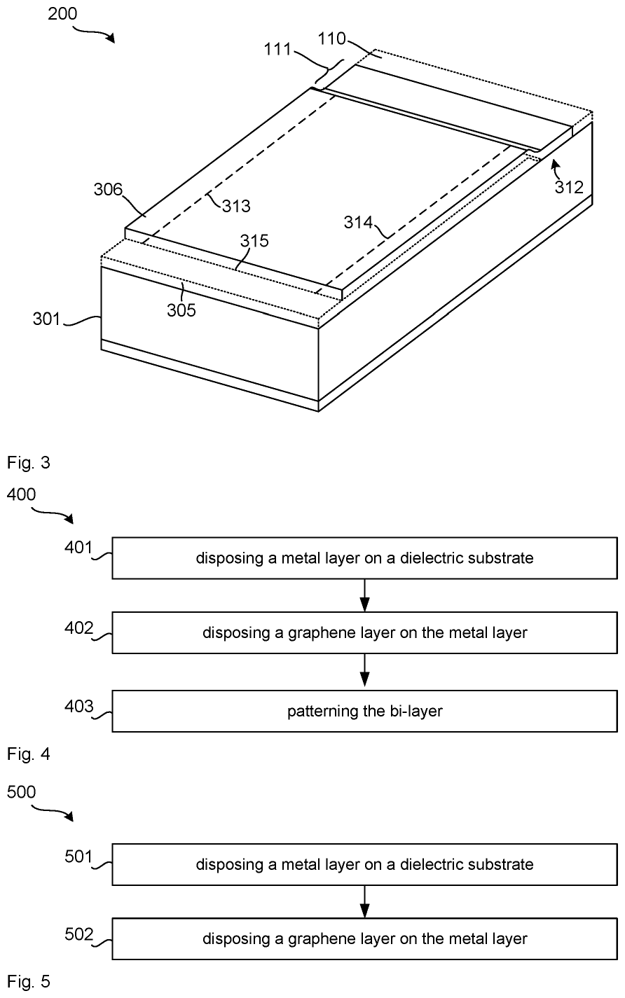

FIG. 3 illustrates yet a further example, where the gap 111 in metal layer 305, as described with reference to FIG. 1, is used to define an exposed area 312 where the graphene layer 306 directly attaches to the dielectric layer 301. In that sense, the gap 111 fulfils two purposes: as an insulating distance between electrode 110 and metal layer 305 as well as an “attachment area” to secure the graphene layer 306 to the dielectric layer 301. The mechanical attachment can be further improved by providing further attachment areas on the other sides of the chip. In FIG. 3, reference numerals 313, 314 indicate potential boundaries of the metal layer 305, which can be manufactured by using masks in a gold sputtering process. Where the graphene layer 306 extends over these boundaries 313, 314 the graphene layer 306 is directly attached to the dielectric layer 301. In the example of FIG. 3, the boundaries 313, 314 and therefore the attachment areas, are on the perimeter of the chip 200. It is noted here that the dielectric layer 301 may be significantly larger than the graphene layer and the pattern 108 described with reference to FIG. 1. As a result, only a very small area, as defined by the metal layer 305, of the dielectric layer 301 actively contributes to absorbing electromagnetic radiation. The graphene layer 306 is then directly attached to the dielectric layer 301 on the perimeter of the metal layer 305.

There is a third boundary 315 at one end of the chip. In this example, however, the metal layer 305 extends past the boundary and past the graphene layer 306, so that the metal layer 305 remains exposed. This is useful to add an electrical contact to the metal layer 305 to apply a bias voltage between the metal layer 305 and the electrode 110 on the other side of gap 111. In other words, the area where the metal layer 305 is exposed may be referred to as a contact area. It is noted that there may be a wide variety of different layouts of the contact area and attachment areas. In particular, the contact area can be relatively small while the attachment areas could be non-contiguous and scattered across the chip. The different layouts of attachment areas and contact areas individually and in combination apply to chips 100, 200 and 300 as well as other embodiments.

### Graphene Transfer

In one example, which applies to chips 100, 200 and 300, the graphene is first grown separately using Chemical Vapour Deposition and then transferred onto the metal layer 305. This can be achieved by using a thermal release tape or by using Poly(methyl methacrylate) (PMMA) to transfer the graphene to the metal layer 305. The PMMA method comprises spin-coating a layer of PMMA onto the graphene as a support. The metal catalyst, on which the graphene is grown, is then etched away. The PMMA/graphene stack can then be transferred onto the metal layer 305 with the graphene facing the metal layer 305. The PMMA can then be removed by solvents. Further details are provided below.

As an example, a different type of graphene can be used that does not involve the method of the previous paragraph. However, if a different graphene type is used, a second electrode may need to be placed on top of the graphene for applying the bias voltage across the graphene to tune its conductivity. This is opposed to creating an opening 111 (or gap) to define the second electrode from the metal layer by etching the metal layer.

### Methods of Manufacturing

FIG. 4 illustrates a method 400 for manufacturing a chip, such as chip 100 in FIG. 1. This is an example of a method of manufacturing the chip, used to explain the main principles of chip manufacturing. However, manufacturing the chip is not limited to the example method presented here.

The chip is manufactured by disposing 401 metal layer 105 on a dielectric substrate. This can be achieved by sputtering or thermal evaporation. The metal layer 105 may be shaped into a desired shape, which, advantageously, may leave some areas of the dielectric layer 101 exposed.

In an example, a stock metal layer/dielectric substrate configuration may be obtained, in which deposing the metal layer on dielectric substrate would not be necessary. The proceeding manufacturing could then be performed on this configuration to obtain the chip. However, disposing the metal layer on the dielectric substrate has advantages, such as the metal layer 105 being in a desired shape. Such advantages may be useful for the particular use of the chip. Therefore, using a stock metal layer/dielectric substrate configuration to manufacture the chip may not always be desired.

The next steps is to dispose 402 graphene layer 106 on the metal layer 105. This forms a bi-layer 107 comprising the metal layer 105 and the graphene layer 106 in the sense that resonance between bi-layer 107 and grounding electrode 104 can be tuned by application of a voltage to the graphene layer 106. The bi-layer 107 is then patterned 403 to provide absorption of the electromagnetic radiation by the chip. The patterning can be performed with a photo resist (a mask) and then the application of oxygen plasma to etch the graphene layer 106 followed by argon etching of the metal layer 105 underneath. The photo resist defines a shape of the one or more superimposed trenches that form the bi-layer pattern. As a result, the pattern extends, at least in part of the pattern, through the graphene layer 106 and the metal layer 105 down to the dielectric layer 105. In other words, patterning the bi-layer through the graphene layer and the metal layer simultaneously with a design comprising one or more superimposed trenches. It is important to note that the bi-layer is etched together and does not separate during the subsequent etching step.

In another example, the graphene layer 106 may be deposited on the dielectric substrate and then the metal layer 105 may be deposited on the graphene layer 106. This configuration would still constitute a bi-layer and the bi-layer may still be patterned using the methods described here. In this example, a stock graphene layer/dielectric substrate configuration may be obtained, in which deposing the graphene layer on dielectric substrate would not be necessary. The metal layer 106 would then be deposited on the graphene layer to form the bi-layer and pattering of bi-layer may then occur.

As described above, patterning the bi-layer involves etching the bi-layer, where etching the bi-layer comprises etching the graphene layer with a first etching agent: and after etching the graphene layer, etching the metal layer with a second etching agent. In an example, the first and second etching agents are the same etching agent. In particular, the etching agent may be a mixture of oxygen and argon plasma. In this sense, the bi-layer is patterned simultaneously using a single etching agent. If the first and second etching agents are different, the process of patterning the bi-layer can still be considered as simultaneous. For example, in the case where oxygen plasma is used to etch the graphene and argon plasma is used to etch the metal layer, oxygen gas is first introduced into a plasma chamber to hold the chip. After the graphene is etched by turning the gas into a plasma, the oxygen gas is stopped from entering into the plasma chamber and the argon gas is introduced. This process of patterning the bi-layer is considered simultaneous as the chip, which possesses the bi-layer, never leaves the plasma chamber and the mask remains on the chip.

In another example, the bi-layer pattern can also be formed by direct writing methods or lithography techniques, such as focused ion beam (FIB) or laser cutting. In other words, patterning the bi-layer comprises using a directed beam to create the one or more trenches in the graphene layer and the metal layer of the bi-layer. In this example, the pattern design is written into automated control software without the need to use a physical mask.

FIG. 5 illustrates a method 500 for manufacturing a chip, such as chip 200 in FIG. 2 or chip 300 in FIG. 3. The chip is manufactured by disposing 501 metal layer 205 on a dielectric substrate 201 to provide absorption of the electromagnetic radiation by the chip 200. The dielectric substrate 201 is exposed over an area 212 of the dielectric layer. Then, a graphene layer is disposed 502 on the metal layer 205 to form a bi-layer comprising the metal layer 205 and the graphene layer 206 and to bring the graphene layer 206 into direct contact with the dielectric layer 201 where the graphene layer 206 extends over the exposed areas 212.

### Example Chip

This disclosure provides a method for of graphene growth, transfer, device fabrication and characterisation. A tuneable frequency selective absorber operating at a designed frequency of 0.2 THz was implemented. The tuneability is three-fold: (1) Resonant amplitude of the designed plasmonic mode, (2) Frequency tuning of the plasma resonance and (3) a broadband modulation over the full 0.1-1 THz available range. Of note, the active region of the device consists of a graphene/gold metasurface bilayer; the gold showing a strong resonant response, which is complemented from solid tuneability of the graphene. An example device is built on a commercial Rogers5880 laminate, tailored for high frequency communications devices. This disclosure provides an experimental realisation of a large area graphene THz device, where the graphene itself is patterned into the designed meta-surface.

This disclosure can be used for realising a large range of tuneable THz metasurface devices. The presented approach can be adapted to many metasurface designs, on many different substrates, realising a wide range of applications in THz communications and the development of highly desired reconfigurable THz components built for-purpose.

FIG. 7 shows the schematic drawing of the 0.2 THz metasurface-based resonant absorber, which features a gold thin-film pattern consisting of periodically arrayed Jerusalem-cross slots on a grounded 254 μm-thick Rogers 5880LZ substrate. At the first (0.2 THz) resonant mode of the grounded metasurface unit, the absorber is equivalent to an RLC parallel resonant circuit, with the resistance coming from the dissipative gold film and Rogers substrate with a loss tangent of 2.3 at the 0.2 THz band. Inductance and capacitance are determined by the resonant structure. As a result, the presented design can function as a frequency selective resonant absorber. The response of this absorber was simulated using Finite Element Method (FEM) analysis.

The designed Jerusalem-cross slot unit features compact dimensions of 450 μm×450 μm which is advantageous in realizing a high quality-factor resonance and insensitivity to the incident angle of THz radiation. The THz metasurface absorber can be modelled as equivalent to an RLC resonant circuit for which a maximum power absorption occurs at the resonant frequency and where the resonant resistance is well-matched with the wave impedance of the THz radiation. In this case, equivalent inductances and capacitances are generated from the metasurface structure and corresponding resistances from the conductivity of the graphene/gold bilayer and dissipation properties of the Rogers5880 substrate. To investigate the electromagnetic behaviour of the frequency-selective metasurface absorber and optimize its overall performance, detailed three-dimensional full-wave modelling and simulations are carried out by using the software CST Microwave Studio.

Within the model, the graphene is treated as a surface impedance, quantified through the complex conductivity obtained through THz time domain spectroscopy (see methods). The real and imaginary parts of the conductivity, in the region of interest (0.1-0.3 THz), were observed to be 37 mS and 10 mS respectively. Auxiliary measurements have shown tuning of both parts of the complex conductivity of approximately 20%.

There are two aspects in realising the successful THz absorber device, as depicted in FIG. 7. Firstly, the device is built on an appropriate substrate with desirable properties. For this device, commercially available Rogers5880LZ Duroid was chosen as the ideal candidate with a dielectric constant of 2.2. Secondly, the graphene film adheres to not only the Rogers laminate, but also the gold region of the metasurface and electrical contact. This can be problematic as graphene adherence to gold is notoriously difficult. Suitable films were successfully transferred onto the Rogers5880/gold base structure. The graphene films were at least 3 cm×3 cm in size and consist of high uniformity (minimal wrinkling) and no holes/defects. Any wrinkles in the film or hole defects may result in device failure at later fabrication steps.

Successfully transferring the graphene film directly onto gold and the Rogers substrate allowed the metasurface region (see FIG. 7) to be directly patterned into both the gold and graphene. This fabrication approach and bilayer metasurface design permitted a functional device with advantageous characteristics. By having the pattern in the gold and graphene bilayer together, the gold portion supports the bulk of the plasmonic resonant activity, while the graphene provides tuneability to the device. This tuning is also achieved without the need of a dielectric layer to build up the field, or a gating electrode: both of which would be detrimental to the device performance.

Further, the bilayer results exceed those when considering the gold and graphene metasurface separately. Without the graphene, the gold cannot tune and without the gold, the graphene does not support plasmonic resonances. The successful bilayer is also important as, for this device, it is difficult to add a dielectric layer or add an unpatterned graphene film. Including a dielectric on top of the gold screens the THz field, while adding a full graphene sheet over the gold metasurface was observed to completely damp any resonant behaviour. In fact, no evidence of any plasmonic modes could be observed for the gold metasurface with a full graphene sheet transferred on top.

Interestingly, in adopting from a gold metasurface to the bilayer all resonant modes from 0.1-0.6 THz were supported in the device. This is detailed in FIG. 2(c). Importantly, this includes the fundamental 0.2 THz absorbance, for which this device was designed. The frequency of each mode has shifted very slightly, and the strength of the modes has increased. Above 0.6 THz higher order modes present in the gold-metasurface have been suppressed in the bilayer structure. However, these are well away from the region of interest that this structure was designed for.

Despite these changes to the frequency and amplitude of the modes, the bilayer metasurface now permits a high degree of tuneability in the strength of the modes, their resonant energy and an overall broadband modulation. To analyse the tuneability of the selective absorber, it is assumed that the device contains a single port with a corresponding S₁₁ parameter. In doing so, we can characterise the device in a time domain THz spectroscopy setup graphically presented in FIG. 1(a). Here the S11 parameter, a ratio of the reflected electromagnetic power to the incident electromagnetic power can be directly obtained through the power spectrum measured in the time domain spectroscopy setup. This process is detailed in the methods section.

FIG. 1(c) gives the device S11 parameter for applied voltage from 0-6V. In transitioning from a gold metasurface to gold/graphene bilayer, the overall resonant behaviour of the structure has remained.

Inclusion of the graphene metasurface has reduced the resonant frequency by 0.01 THz and increased the loss to 18 dB. This small shift in frequency is remarkable considering the relative difference in the conductivity of the gold and graphene layers. Thus, with careful fabrication of the bilayer structure, the desired characteristics for a gold-only device can be supported, with the added ability of tuning from the graphene inclusion.

With increasing voltage, the clear tuneability of the device is showed. Firstly, a broadband response of 5 dB reflected in the peak shoulders. Secondly, there is an enhancement of the resonant mode of 7 dB (total change of 12 dB is a summary of both effects) and thirdly, a systematic frequency tuning of 0.05 THz across a voltage range of 0-6V.

The full voltage dependence of the device performance is detailed further in FIGS. 2(a) and (b). Here, it is revealed the device response in nonlinear. For voltages from 0-3V little to no systematic change is seen in any of the peak position, S11 parameter, FWHM or peak area. However, from 3-6V the peak position shifts from 0.192-0.187 THz, S11 parameter from −18 to −25 dB, FWHM from 0.017-0.010 THz and peak area from 0.47-0.38. It should be noted that the S-parameters presented in FIG. 2(b) are fitted with the broadband response omitted. Thus, they reflect the direct enhancement of the resonant mode independent of any wider frequency effects. Thus, the total change in the peak strength shown in FIG. 1 is governed by a dual response from the graphene part: a 5-6 dB broadband modulation and a 7 dB direct enhancement of the resonance amplitude. Therefore, we can conclude there is a direct amplification of the designed plasmonic resonance, not a simple reduction of signal from the broadband graphene absorption.

Interestingly, the FWHM exhibits a stronger decrease (37.5%), than the peak area (21.2%) across the voltage range. This is reflected in an improvement of the quality factor of the mode increasing from 11.8-18.7 at 6V applied. Thus, the biased graphene has the effect of decreasing the energy lost within the resonance mode. Not only does the biased graphene amplify the absorption band, but also increases its quality with a reduction in bandwidth.

The frequency tuning of the device also follows the nonliner property. The resonant frequency is consistent until above 3V where a shift to lower photon energy is observed. In comparing to the 0V resonant frequency at 0.191 THz, the total shift across 6V applied voltage is 5 GHz, or 2.5%.

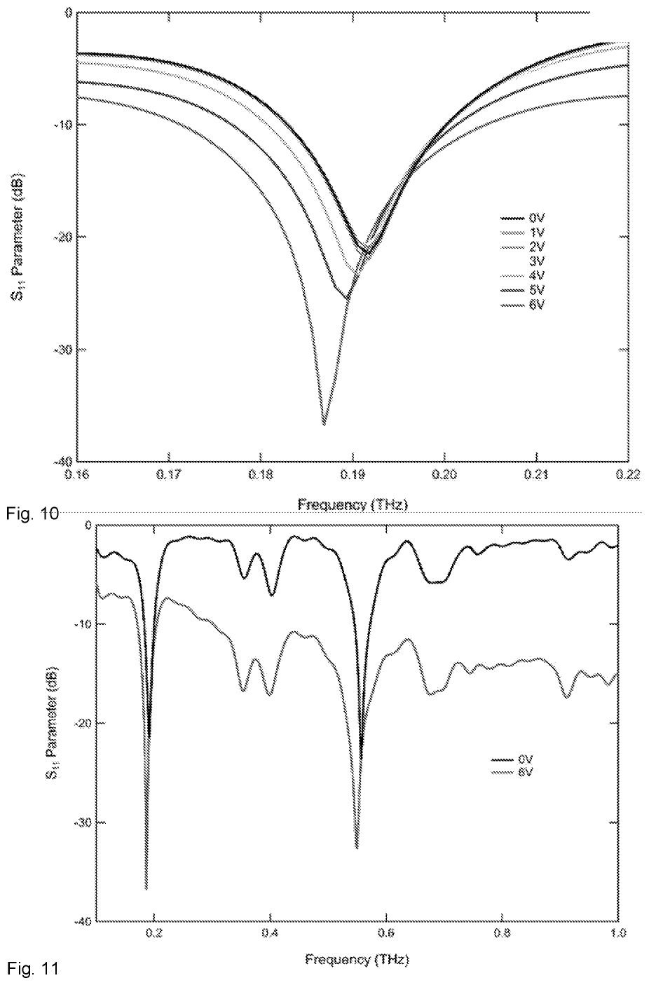

It should be noted that the characteristics of the bilayer were repeated with the polarity reversed (second panel in FIG. 10). Further, for voltages above 6V the device was observed to degrade. Details of this are presented in the ESI, along with comprehensive data for all the resonant modes observed between 0.1-0.6 THz.

### Broadband Modulator

Superimposed on the resonant modes, is a broadband modulation of the THz waveform. This is clear across the entire available spectrum, depicted in FIG. 7. The asymptotic shape of the curves at 0.19 THz and 0.56 THz arise from relative shifting of the resonant modes with the change in voltage. Although the modulation is unclear in these regions, they do provide experimental validation of the frequency tuneability of the bilayer. This effect is also present, to a lesser degree, for the 0.36 THz and 0.40 THz resonances. This behaviour invites the use of the bilayer as a THz modulator.

Three transmissive windows are present between 0.23-0.32 THz, 0.43-0.50 THz and 0.72-1 THz. In the former, the modulation depth, defined as

$$MD = \frac{100 \times \vert R ( 0 V ) - R ( 6.2 V ) \vert}{R ( 0 V )}$$

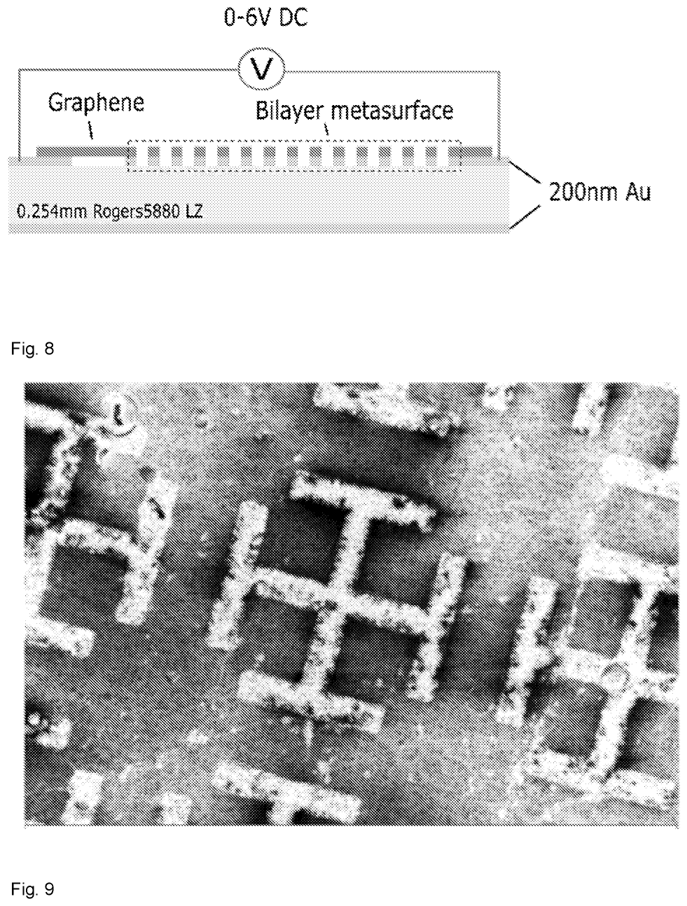

is between 80-90%. For the 0.43-0.50 THz window, this increases to 90-93%. From 0.72-1 THz the modulation depth varies from 94-96%. This is extraordinary in the absence of a dielectric between the graphene and the metal layers and such a low applied voltage. The full frequency characteristics of the modulation depth at 6.2V is given in FIG. 8. There is an overall frequency dependence on the modulation behaviour of the bilayer. That is, the modulation depth increases with photon energy. In the presented range (at 6.2 V), the modulation depth is 65% at 0.1 THz increasing steadily to 90% at 0.31 THz and remaining above 95% for frequencies above 0.73 THz. With spectral disruptions close to the plasma resonant frequencies, arising the from the frequency tuning characteristic, it is difficult to ascertain the mathematical relationship between the modulation depth and frequency across the full range at this voltage.

### Graphene Synthesis and Characterisation

Graphene films are produced using a Nickel catalysed CVD process (99% purity, annealed). This process includes an initial vacuum step to produce a higher quality graphene film and lineolic acid dissolved in ethanol (60% v/v) is substituted for soybean oil.

In one example, the following graphene production protocol may be used:
1. Nickel foil (99% purity, annealed) 15 cm×12 cm is IPA cleaned and then rolled into a cylinder such that the 12 cm length just touches the opposite side.
2. Two ceramic boats 3*3*0.2 cm are loaded with 60 μL of Lineolic acid (60% in ethanol).
3. The boats and foil are loaded into a 50 mm inner diameter tube furnace reactor with a hot zone of 30 cm, they are orientated such that the boats are on either side of the foil with a 1 cm gap, the foil is placed at the centre of the hot zone.
4. The furnace is then sealed.
5. The furnace is heated to 150° C. and the tube is evacuated to a base pressure of 50 m Torr.
6. The vacuum is closed, and the temperature is held for 5 mins.
7. After the time vacuum line is opened and the pressure brought back to 50 m Torr.
8. The vacuum is then closed, and the furnace is brought to 950° C.
9. The temperature is then held for 2 minutes.
10. After the time expires the furnace is switched off and the vacuum is opened.
11. When the temperature has reached 850° C., the tube is shifted out of the furnace such that the area of the tube with the foil contained is exposed to open air and not the hot zone of the furnace.
12. The sample is left to cool to room temperature.
13. Once at room temperature the vacuum line is closed, and the tube brought back to atmosphere.
14. The tube is then opened, and the foil removed.
15. The nickel foil is now coated with a thin graphene like film.

In a further example, the following transfer protocol may be used:
1. Graphene sheet is cut to the desired size, 25×25 mm.
2. PMMA 950K Mw dissolved in anisole (5 g/L) is then spun coat onto the foil.
3. The spinning speed used is 2000 rpm.
4. When coated the sample is left to dry for 24 hrs.
5. Once dry the edges of the coated foil is trimmed ˜500 μm.
6. This foil is then placed in an etching solution of 0.5M FeCl3 dissolved in water.
7. The sample is left for 24 hrs.
8. Once the Nickel is dissolved the PMMA coated graphene film is transferred to clean DI water.
9. From here it can be transferred and used to make a device.

In yet further examples, the graphene may be manufactured as described in PCT applications WO2017/027908 or WO2018/161116, noting that other ways of making graphene and their result can be used.

Terahertz characterisation of the graphene films was performed on a fibre-coupled Batop time-domain spectroscopy (TDS) system in transmission geometry. Photoconductive antennae (PCA's) were utilised for both THz production and photo detection. Graphene films were transferred onto a PTFE substrate for characterisation. The substrate was designed to be 3 mm thick to achieve an optimal trade-off between measured signal and avoiding back reflections in the time domain signal. The complex conductivity of the graphene film is extracted and subsequently the scattering rate, carrier mobility and carrier density. From THz-TDS, the carrier mobility and carrier density are 1393 cm²V⁻¹S⁻¹ and 17×10¹³ cm⁻² respectively. These were obtained from the DC conductivity of 37 mS and a scattering time of 209 fs (scattering rate of 0.76 THz).

### Fabrication of Graphene/Gold Bilayer Device.

Commercial 0.254 mm thick Rogers 5880LZ laminates were used as the device substrate. The ground plane was prepared with 220 nm sputtered gold film. The obverse side received the same gold deposition with a hard mask to define the metasurface bilayer and contact regions. Post deposition, the obverse side was treated with 30 W Argon reactive ion etch for 1 min. Nickel/graphene foils (25 mm×25 mm) were spin coated with poly(methyl methacrylate) (PMMA) polymer. Nickel foil was then dissolved in a FeCl₃ bath. The subsequent graphene/PMMA structure was transferred onto the pre-prepared Rogers substrate. Finally, the PMMA was dissolved in anisole and the sample allowed to dry. Graphene films were then transferred to the Rogers laminates using a wet transfer technique.

The graphene/gold bilayer pattern was realised using a standard photolithography procedure, that is, spin-coating photoresist, UV light exposure and photoresist development. The patterned device chip with the photomask protection layer was etched using a novel reactive ion etching process. Firstly, an O₂ plasma to remove the unprotected graphene, followed by etching in Ar (a chemically inert gas) to remove the unprotected gold layer, and finally a short, final O₂ plasma etching was applied to clean the device chip Electrical connection of external wires to the gold contacts of the metasurface were made using silver epoxy. While using O₂ plasma to etch the graphene and Ar plasma to etch the gold layer, the disclosed method is not limited to these plasmas. It is noted that any combination of chemically reactive gas and a chemically inert gas would be sufficient for patterning the device chip.

### Terahertz Characterisation of Bilayer Metasurface

Terahertz (THz) characterisation of the device was performed on a fibre-coupled Batop time-domain spectroscopy (TDS) system in reflection geometry. Photoconductive antennae (PCA's) were utilised for both THz production and photo detection. To quantify the performance of the absorber, the reflected power of the electromagnetic wave, Ē^{Ref1}(ω) of the metasurface device, Ē_{MS}^{Ref1}(ω), is ratioed to a reference measurement (Ē_{Ref}^{Ref1}(ω)), made with a gold backed Rogers5880LZ substrate with no bilayer metasurface. We consider the absorber to be a single-port device, with a corresponding S₁₁ parameter, given through the relation S₁₁=10 log(R). Here R is the ratio (reflectance) of the sample and reference power spectrum,

$$R = \frac{{{\overline{E}}_{MS}^{Refl} ( ω )}^{2}}{{{\overline{E}}_{Ref}^{Refl} ( ω )}^{2}}$$

### Tuneable Performance at 0.2 THz

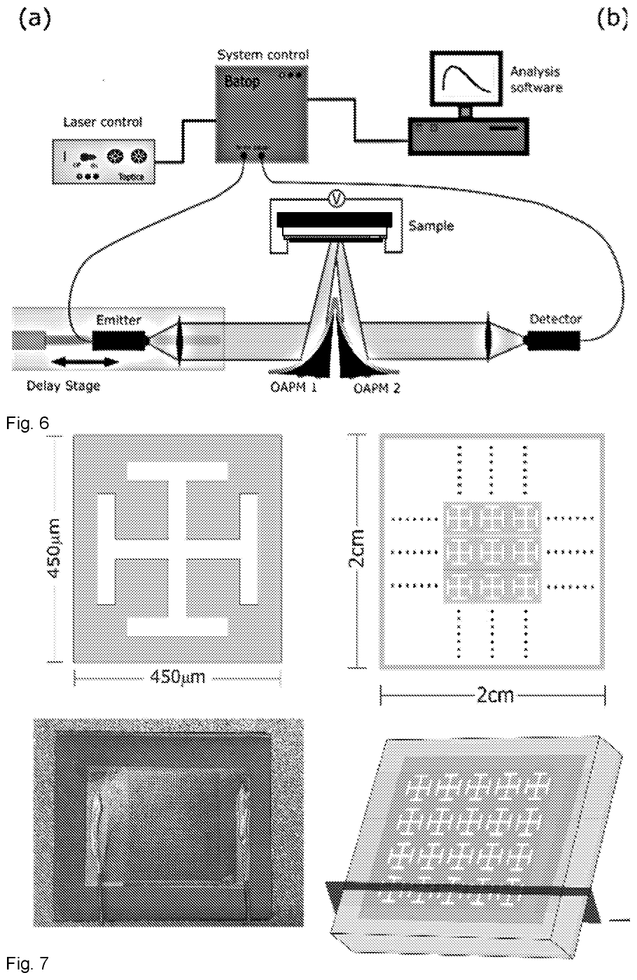

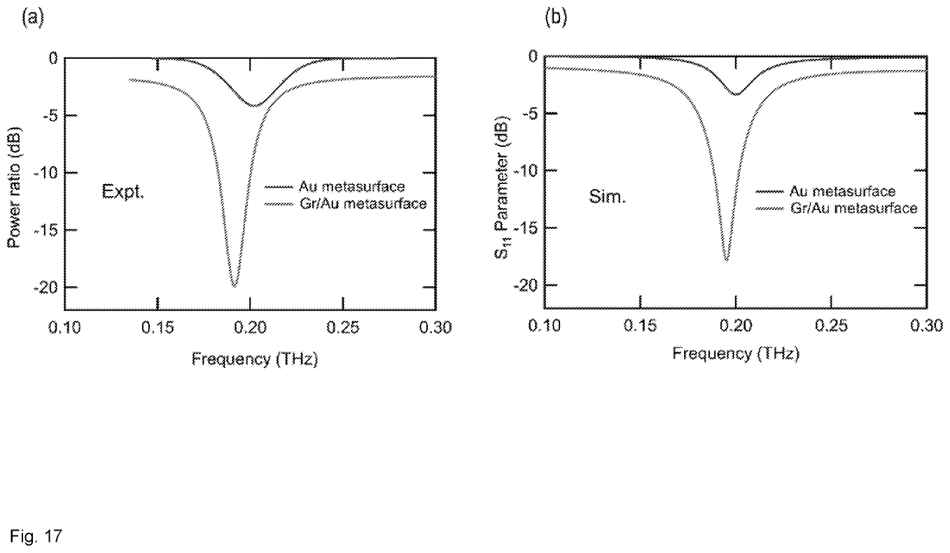

THz-Time Domain Spectroscopy is used to study the performance of the absorber (the measurement set-up is shown in FIG. 6). In reflection geometry the reflected THz power (the electromagnetic wave after it has interacted with the device) is equated as a ratio to the incident THz beam (the electromagnetic wave before interacting with the device), characterised by the S₁₁-Parameter for a single port device. As such, the real-world performance of the absorber can be directly compared to the theoretically modelled response in CST (FIG. 17).

FIG. 17a shows the experimental frequency responses for the graphene/gold bilayer metasurface compared to the same design with a gold-only metasurface layer. A high-quality resonance at 0.2 THz is produced in both cases, which agree closely with simulated S₁₁ parameters calculated using CST, presented in FIG. 17b. A very good agreement is obtained between the experimental and simulation results, confirming the validity of the design and experimental implementation of the novel graphene/gold bilayer metasurface device being successful.

FIG. 12 shows the THz power ratio, Su, for the absorber at the designed 0.2 THz resonance with an applied voltage of 0-6V. With increasing voltage, a systematic tuneability of the device resonant amplitude and frequency is displayed. Firstly, there is a 16 dB change of the signal power at resonance, significantly stronger than those earlier outlined reports for THz metamaterials tuned through graphene. Further, there is a phase shift, observed as a frequency tuning of 5 GHz across 0-6V applied. The tuning is achieved using a simple biasing scheme and at a very low voltage (0-6V), which is advantageous compared to those reported in literature that use a more complicated gating electrode scheme and usually much higher bias voltages.

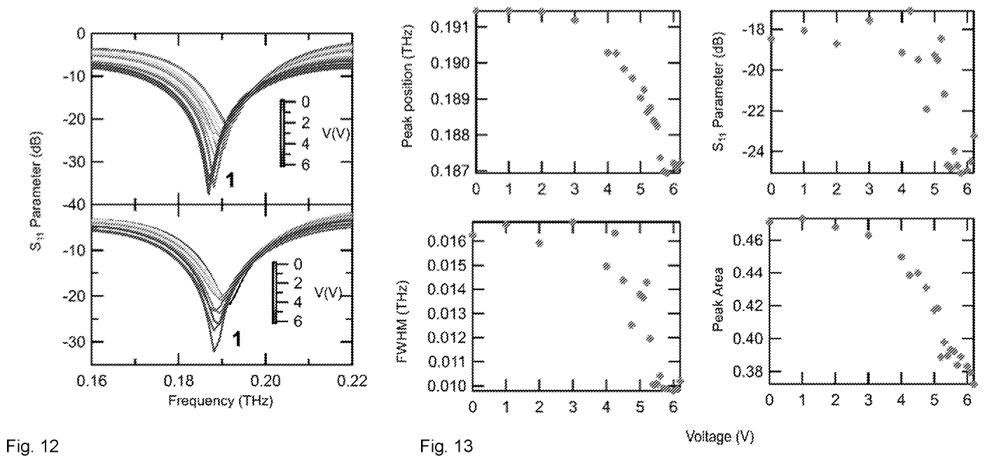

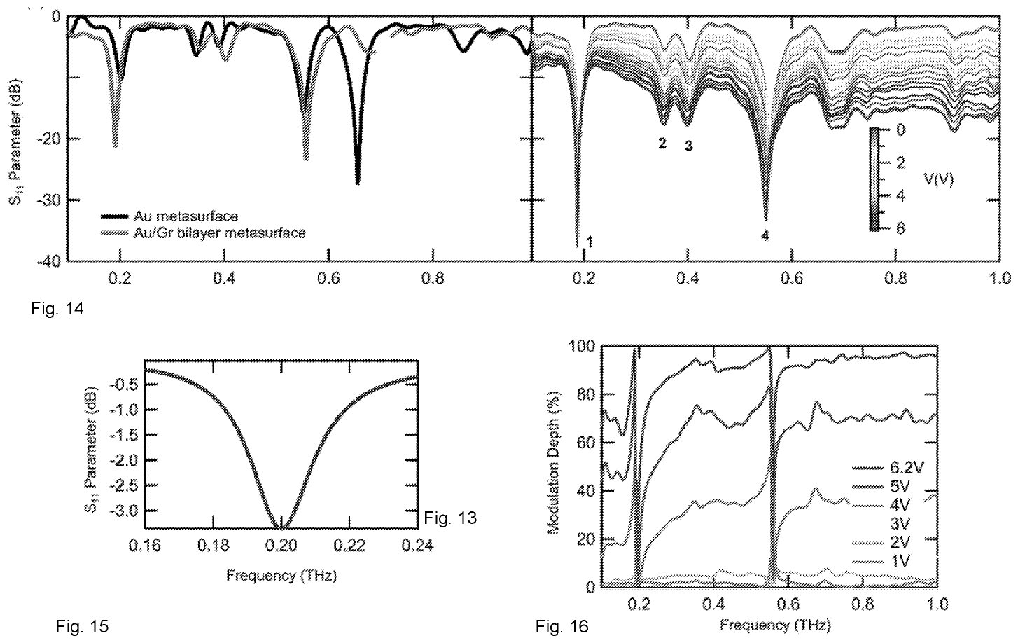

The voltage dependence of the device tuneability is shown in FIG. 13. Interestingly, the voltage dependence is non-linear. For voltages from 0-3V little change is observed in either the resonance peak position or amplitude. However, from 3-6V the changes become more profound: the resonance position shifts from 0.192 to 0.187 THz and the power amplitude from −18 to −25 dB. Also, the resonance FWHM drops from 0.017 to 0.010 THz and corresponding area from 0.47 to 0.38. This is reflective of an increase in the resonance quality factor from 12 to 19 with the applied voltage.

The tuning mechanism of the absorber is attributed to two major effects, both reliant on the graphene in the bilayer. Firstly, the tuned graphene conductivity changes the equivalent resistance (R) of the bilayer in the RLC resonant circuit model, thus changes both the resonant frequency and amplitude. In other words, the tuning changes the impedance matching of the 0.2 THz radiation into the metamaterial resonator structure affecting the resonant frequency and the maximum power absorption at the resonant frequency. With increasing voltage, the improved impedance matching of the device gives a 7 dB stronger resonance at 0.2 THz as well as a 5 GHz frequency shift. Likewise, the improved matching condition is verified through a rise in the quality factor of the 0.2 THz mode.

Secondly, the broadband absorption of the incident THz waveform is tuned through alteration of the graphene Fermi level and thus its intraband conductivity. This is shown experimentally in a 9 dB signal power drop adjacent to the resonance peak (outside of the resonant frequency), with increasing voltage. This effect is also observed in the wider THz spectrum as discussed in the next section. The total 16 dB amplitude and 5 GHz frequency tuneability detailed in FIG. 13, is a superposition of the two effects described above.

### Broadband Operation up to 1 THz

Apart from the designed 0.2 THz resonance the device presents an intriguing broadband response. A series of auxiliary modes are found at 0.36 THz, 0.40 THz and 0.56 THz, as can be seen in FIG. 14 (right panel). These modes are also observed in the gold-only device, thus due to the resonant circuit design. As with the 0.2 THz feature, these resonances also exhibit significant amplitude and frequency tuneability with applied voltage. Although, the tuning is less pronounced than that at 0.2 THz resonant peak. A summary of each resonance and its behaviour at 0V and 6V applied can be found in Table 1.

TABLE 1
Summary of broadband device characteristics from 0-6 V. S11-parameters
presented do not include the graphene broadband absorption effect.

| Peak | f(0 V) THz | f(6 V) THz | Δf GHz | S₁₁(0 V) dB | S₁₁(6 V) dB | ΔS₁₁ dB | Q(0 V) | Q(6 V) | ΔQ |
|---|---|---|---|---|---|---|---|---|---|
| 1 | 0.192 | 0.187 | 5 | −18 | −25 | +7.0 | 12 | 19 | +7 |
| 2 | 0.356 | 0.353 | 3 | −4.1 | −5.9 | +1.8 | 14 | 9 | −5 |
| 3 | 0.402 | 0.399 | 4 | −5.4 | −6.6 | +1.2 | 15 | 14 | −1 |
| 4 | 0.558 | 0.449 | 9 | −18 | −17 | +1.0 | 21 | 18 | −3 |

Superimposed on the resonant modes, there is a broadband modulation of the THz waveform. This is clear across the entire available spectrum, depicted in FIG. 16. Three transmissive windows are present between 0.23-0.32 THz, 0.43-0.50 THz and 0.72-1 THz. In the former, the modulation depth, defined as

$$MD = \frac{1 \; 00 \times \vert R ( 0 V ) - R ( 6.2 V ) \vert}{R ( 0 V )}$$

is between 80%-90%. For the 0.43-0.50 THz window, this increases to 90%-93%. From 0.72-1 THz the modulation depth varies from 94%-96%. There is an overall frequency dependence on the modulation behaviour of the bilayer, seen in FIG. 16. That is, the modulation depth increases with photon energy. The observation of the effective tuning effect across the whole measured THz frequency band verifies that the bilayer design can be adapted for tuneable metamaterial devices covering full 0.1-1 THz range. It is expected this would also apply to similar structures operating above 1 THz.

### Graphene ET122-124 Production Protocol

The following description provides further detail on the production of the graphene layer 106/206/306.

First, a Nickel foil (99% purity, annealed) 15 cm×12 cm is IPA cleaned and then rolled into a cylinder such that the 12 cm length just touches the opposite side. Then, two ceramic boats 3*3*0.2 cm are loaded with 60 μL of Lineolic acid (60% in ethanol). The boats and foil are loaded into a 50 mm inner diameter tube furnace reactor with a hot zone of 30 cm, they are orientated such that the boats are on either side of the foil with a 1 cm gap, the foil is placed at the centre of the hot zone.

After that, the furnace is sealed and heated to 150° C. and the tube is evacuated to a base pressure of 50 mTorr. Then, the vacuum is closed, and the temperature is held for 5 mins.

After the time vacuum line is opened and the pressure brought back to 50 mTorr. The vacuum is then closed, and the furnace is brought to 950° C. The temperature is then held for 2 minutes. After the time expires the furnace is switched off and the vacuum is opened.

When the temperature has reached 850° C., the tube is shifted out of the furnace such that the area of the tube with the foil contained is exposed to open air and not the hot zone of the furnace. The sample is then left to cool to room temperature.

Once at room temperature the vacuum line is closed, and the tube brought back to atmosphere. The tube is then opened, and the foil removed. The nickel foil is now coated with a thin graphene like film.

### Transfer Protocol

The following description provides further detail on the transfer of graphene onto the metal layer 105. A graphene sheet, as created according to the above method, is cut to the desired size, such as 25×25 mm. PMMA 950K Mw is then dissolved in anisole (5 g/L) and spun coat onto the foil. The spinning speed used may be 2000 rpm.

After the spinning, the coated sample is left to dry for 24 hrs. Once dry, the edges of the coated foil is trimmed by about 500 μm. Then, this foil is placed in an etching solution of 0.5M FeCl₃ dissolved in water. After that, the sample is left for 24 hrs. Once the Nickel is dissolved, the PMMA coated graphene film is transferred to clean DI water. From here it can be transferred and used to make a device.

### SUMMARY

This disclosure provides a highly tuneable THz frequency selective absorber based a graphene/gold bilayer metasurface structure. The bilayer design was developed through theoretical modelling and optimisation followed by a holistic experimental approach covering graphene production, transfer, device patterning, and characterisation. For the designed 0.2 THz frequency selective absorber, a benchmark resonance quality factor of 19 (at 6V applied) is observed in conjunction to a large 16 dB amplitude tuning and 5 GHz frequency tuning. The device behaves as expected from simulation, proving the bilayer implementation provides a predictable response. This is useful for producing commercially viable and scalable electronics.

Additionally, higher order resonant modes are revealed at 0.36 THz, 0.40 THz and 0.56 THz, also exhibiting amplitude and frequency tuneability, with a broadband modulation consistently above 90% up to 1 THz. The successful experimental implementation of the graphene/gold bilayer devices opens the opportunity of realising a range of high-impacting tuneable, flexible, reconfigurable, and programmable THz metamaterial devices.

The observed tuning effects can be attributed to two major mechanisms. First, the change of the conductivity in the voltage-biased graphene/gold bilayer (upper electrode) changes the impedance matching of the resonant structure to the wave impedance of the THz radiation, thus changes the resonant frequency and its amplitude, as that predicted by the RLC resonant circuit model. Second, the change of the graphene surface conductivity alters the graphene intraband absorption of the THz radiation. This is confirmed by the tuning effects observed across the entire measured THz bands including the resonant peaks and non-resonant regions. The first mechanism based on the RLC resonator effect is more dominant towards lower frequency side (stronger change in 0.2 THz than other peaks) and the second effect of the intraband THz absorption of graphene becomes stronger towards higher THz frequency bands, as shown in FIG. 16 where the broadband amplitude modulation increases with higher frequency.

The device is built on a flexible commercial high frequency laminate, therefore, potentially implementable in practical THz electronic circuits and flexible electronics. The graphene/gold bilayer architype can be immediately adapted to numerous numerically modelled metamaterial structures currently in the literature pertaining to tuneable THz electronics devices.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A method for manufacturing a device, the method comprising:
disposing an unpatterned graphene layer on a substrate comprising an unpatterned metal layer to form an unpatterned graphene-metal bi-layer attached to a surface of the substrate; and
patterning the bi-layer through the graphene layer and the metal layer with a design comprising one or more superimposed trenches;
wherein each of the one or more trenches extend through the graphene layer and the metal layer to provide interaction with electromagnetic radiation.

2. The method of claim 1, wherein the patterning is performed using a single mask defining the design to thereby create the trenches through the graphene layer and the metal layer in a single patterning step.

3. The method of claim 2, wherein the method further comprises using the single mask for performing both of etching of the graphene layer and etching of the metal layer.

4. The method of claim 3, wherein the method further comprises:
etching the graphene layer with a first etching agent; and
after etching the graphene layer, etching the metal layer with a second etching agent.

5. (canceled)

6. (canceled)

7. The method of claim 1, wherein the method further comprises creating a gap in the metal layer to define a first electrode and a second electrode.

8. (canceled)

9. The method of claim 7, wherein the gap is created prior to disposing the unpatterned graphene layer on the substrate.

10. (canceled)

11. The method of claim 1, wherein patterning the bi-layer comprises using a directed beam to create the one or more trenches in the graphene layer and the metal layer of the bi-layer.

12. A device comprising:
a support layer having a first surface;
a patterned graphene-metal bi-layer comprising a metal layer attached to the first surface and a graphene layer attached on the metal layer, the bi-layer comprising one or more superimposed trenches that extend through the graphene layer and the metal layer to provide interaction with electromagnetic radiation;
wherein
the superimposed trenches align across the graphene layer and metal layer by patterning the bi-layer,
the metal layer comprises a gap to define a first electrode including the one or more superimposed trenches and a second electrode, and
the first electrode is connected to the second electrode by the graphene layer to provide tuneability by modifying a voltage applied between the first electrode and the second electrode and across the graphene layer parallel to the first surface.

13. The device of claim 12, wherein the second electrode is on top of the graphene.

14. The device of claim 1213, wherein
the one or more trenches define an array, and
the array extends across the bi-layer.

15. The device of claim 14, wherein the array is a periodical design to provide the interaction, such as a meta-material structure interaction, with electromagnetic radiation by the device.

16. (canceled)

17. The device of claim 12, wherein the support layer is a dielectric layer.

18. The device of claim 17, wherein the device comprises a resonance structure comprising the dielectric layer, the resonance structure being tuneable by the voltage applied across the graphene layer to thereby tune the interaction with the electromagnetic radiation.

19. The device of claim 17, wherein
the dielectric layer has a second surface opposite the first surface, and
the device further comprises a reflective conductive layer disposed on the second surface to reflect electromagnetic radiation, propagated through the dielectric layer, back into the dielectric layer to form a resonance in the dielectric layer.

20. (canceled)

21. The device of claim 12, wherein the electromagnetic radiation has at least one of: a frequency between 1 GHz and 3 THz; a frequency between 100 GHz and 3 THz; and a frequency greater than 100 GHz.

22. (canceled)

23. (canceled)

24. (canceled)

25. (canceled)

26. The device of claim 12, wherein the graphene layer extends beyond the metal layer to directly attach to the support layer.

27. The device of claim 26, wherein the graphene layer directly attaches to the support layer at one or more of:
the gap between the first electrode and the second electrode; and
an area on the perimeter of the metal layer.

28. A device comprising:
a support layer having a first surface;
a metal layer disposed on the first surface;
a graphene layer disposed on the metal layer, wherein
the metal layer and the graphene layer form a bi-layer,
the graphene layer extends beyond the metal layer to directly attach to the support layer.

29. (canceled)

30. The device of claim 28, wherein the support layer is a dielectric layer, and wherein the graphene layer is directly attached to the support layer by an attracting force between the graphene layer and the support layer

31. The device of claim 28, wherein
the bi-layer comprises one or more trenches to provide interaction with the electromagnetic radiation with the bi-layer, and
the one or more trenches extends through the graphene layer and the metal layer.

32. (canceled)
